(19) United States
(12) Patent Application Publication
(10) Pub. No.: US 2020/0259011 A1
(43) Pub. Date: Aug. 13, 2020

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Masatoshi Arai, Hakusan Ishikawa (JP)

(21) Appl. No.: 16/416,441

(22) Filed: May 20, 2019

(30) Foreign Application Priority Data
Feb. 12, 2019 (JP) 2019-022693

(51) Int. Cl. H01L 29/78; H01L 29/08; H01L 29/10; H01L 29/66

(52) U.S. Cl. CPC H01L 29/7802; H01L 29/66712; H01L 29/1095; H01L 29/0865

(57) ABSTRACT

According to an embodiment, a semiconductor device includes a first electrode, a first semiconductor region, a second semiconductor region, a third semiconductor region, a conductive portion, a gate electrode, and a second electrode. The first semiconductor region is provided on the first electrode. The conductive portion includes a first conductive portion and a second conductive portion separated from each other in a first direction. The first direction is perpendicular to a second direction. The second direction is from the first electrode toward the first semiconductor region. The gate electrode is provided on the conductive portion with a second insulating portion interposed. The gate electrode opposes, with a gate insulating portion interposed, a portion of the first semiconductor region, the second semiconductor region, and the third semiconductor region in the first direction. The second electrode is provided on the second semiconductor region, the third semiconductor region, and the gate electrode.

### CROSS-REFERENCE TO RELATED APPLICATIONS

This application is based upon and claims the benefit of priority from Japanese Patent Application No. 2019-022693, filed on Feb. 12, 2019; the entire contents of which are incorporated herein by reference.

### FIELD

Embodiments described herein relate generally to a semiconductor device.

### BACKGROUND

A semiconductor device such as MOSFET (metal-oxide-semiconductor field-effect transistors) is used for applications such as power conversion. It is desirable that the noise generated by the semiconductor device is small.

### BRIEF DESCRIPTION OF THE DRAWINGS

FIG. 1 is a perspective cross-sectional view showing a portion of a semiconductor device according to an embodiment;

FIG. 2A to FIG. 2D and FIG. 3A to FIG. 3D are process cross-sectional views showing manufacturing processes of the semiconductor device according to the embodiment;

FIG. 4A and FIG. 4C are cross-sectional views respectively showing portions of semiconductor devices according to reference examples and FIG. 4B and FIG. 4D are graphs respectively showing characteristics of the semiconductor devices according to the reference examples; and

FIG. 5A to FIG. 5C are cross-sectional views respectively showing a portion of semiconductor devices according to modifications of the embodiment.

### DETAILED DESCRIPTION

According to an embodiment, a semiconductor device includes a first electrode, a first semiconductor region, a second semiconductor region, a third semiconductor region, a conductive portion, a gate electrode, and a second electrode. The first semiconductor region is provided on the first electrode. The first semiconductor region is of a first conductivity type and is electrically connected to the first electrode. The second semiconductor region is provided on the first semiconductor region. The second semiconductor region is of a second conductivity type. The third semiconductor region is selectively provided on the second semiconductor region. The third semiconductor region is of the first conductivity type. The conductive portion is provided inside the first semiconductor region with a first insulating portion interposed. The conductive portion includes a first conductive portion and a second conductive portion separated from each other in a first direction. The first direction is perpendicular to a second direction. The second direction is from the first electrode toward the first semiconductor region. The gate electrode is provided on the conductive portion with a second insulating portion interposed. The gate electrode opposes, with a gate insulating portion interposed, a portion of the first semiconductor region, the second semiconductor region, and the third semiconductor region in the first direction. The second electrode is provided on the second semiconductor region, the third semiconductor region, and the gate electrode. The second electrode is electrically connected to the second semiconductor region, the third semiconductor region, and the conductive portion.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

In the following descriptions and drawings, notations of n⁺, n⁻ and p⁺, p represent relative heights of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative height of a net impurity concentration after mutual compensation of these impurities when respective regions include both of a p-type impurity and an n-type impurity.

The embodiments described below may be implemented by reversing the p-type and the n-type of the semiconductor regions.

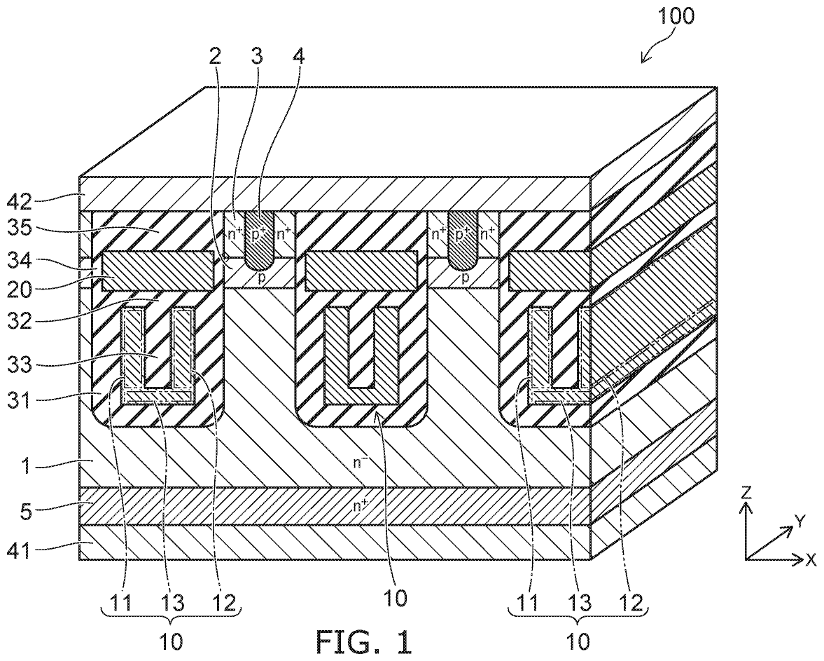

FIG. 1 is a perspective cross-sectional view showing a portion of a semiconductor device according to the embodiment.

The semiconductor device 100 according to the embodiment is, for example, MOSFET. As shown in FIG. 1, the semiconductor device 100 includes an n⁻-type (a first conductivity type) drift region 1 (a first semiconductor region), a p-type (a second conductivity type) base region 2 (a second semiconductor region), an n⁺-type source region 3 (a third semiconductor region), a p⁺-type contact region 4, an n⁺-type drain region 5, a conductive portion 10, a gate electrode 20, a drain electrode 41 (a first electrode), and a source electrode 42 (a second electrode).

An XYZ orthogonal coordinate system is used in the description of the embodiments hereinafter. A direction from the drain electrode 41 toward the n⁻-type drift region 1 is taken as a Z-direction (a second direction). Two mutually-orthogonal directions perpendicular to the Z-direction are taken as an X-direction (a first direction) and a Y-direction (a third direction).

The drain electrode 41 is provided on the lower surface of the semiconductor device 100. The n⁺-type drain region 5 is provided on the drain electrode 41 and is electrically connected to the drain electrode 41. The n⁻-type drift region 1 is provided on the n⁺-type drain region 5. The n⁻-type drift region 1 is electrically connected to the drain electrode 41 via the n⁺-type drain region 5. The p-type base region 2 is provided on the n₋-type drift region 1. The n⁺-type source region 3 and the p⁺-type contact region 4 are selectively provided on the p-type base region 2.

The conductive portion 10 is provided inside the n⁻-type drift region 1 with a first insulating portion 31 interposed. The conductive portion 10 includes a first conductive portion 11, a second conductive portion 12, and a third conductive portion 13 as shown in FIG. 1.

The first conductive portion 11 and the second conductive portion 12 are separated from each other in the X-direction. An insulating portion 33 is provided between the first conductive portion 11 and the second conductive portion 12. The third conductive portion 13 connects the lower end of the first conductive portion 11 and the lower end of the second conductive portion 12.

For example, the length in the Z-direction of the first electrode portion 11 is longer than the length in the X-direction of the first electrode portion 11. The length in the Z-direction of the second electrode portion 12 is longer than the length in the X-direction of the second electrode portion 12.

The gate electrode 20 is provided on the conductive portion 10 with a second insulating portion 32 interposed. The gate electrode 20 is opposed to, with a gate insulating portion 34 interposed, a portion of the n⁻-type drift region 1, the p-type base region 2, and the n⁺-type source region 3 in the X-direction.

The source electrode 42 is provided on the n⁺-type source region 3, the p⁺-type contact region 4, and the gate electrode 20. The source electrode 42 is electrically connected to the n⁺-type source region 3, the p⁺-type contact region 4, and the conductive portion 10. The p-type base region 2 is electrically connected to the source electrode 42 via the p⁺-type contact region 4. An insulating portion 35 is provided between the gate electrode 20 and the source electrode 42, and these electrodes are electrically separated from each other.

For example, the p-type base region 2, the n⁺-type source region 3, the p⁺-type contact region 4, the conductive portion 10, and the gate electrode 20 each are multiply provided in the X-direction, and each extends along the Y-direction.

The operation of the semiconductor device 100 will be described.

In a state where a positive voltage is applied to the drain electrode 41 with respect to the source electrode 42, a voltage higher than a threshold is applied to the gate electrode 20. Thereby, a channel (an inversion layer) is formed in the p-type base region 2, and the semiconductor device 100 is set to the ON-state. Electrons flow from the source electrode 42 to the drain electrode 41 through this channel. Thereafter, when the voltage applied to the gate electrode 20 becomes lower than the threshold, the channel in the p-type base region 2 disappears, and the semiconductor device 100 is set to the OFF-state.

When the semiconductor device 100 is switched to the OFF-state, the positive voltage applied to the drain electrode 41 with respect to the source electrode 42 increases. Thus, the depletion layer spreads from the interface between the first insulating portion 31 and the n⁻-type drift region 1 toward the n⁻-type drift region 1. The breakdown voltage of the semiconductor device 100 can be increased by the spread of the depletion layer. Or, the ON-resistance of the semiconductor device 100 can be reduced by increasing the n-type impurity concentration in the n⁻-type drift region 1 while maintaining the breakdown voltage of the semiconductor device 100.

An example of the material of each component of the semiconductor device 100 will be described.

The n⁻-type drift region 1, the p-type base region 2, the n⁺-type source region 3, the p⁺-type contact region 4, and the n⁺-type drain region 5 include silicon, silicon carbide, gallium nitride, or gallium arsenide as a semiconductor material. When silicon is used as the semiconductor material, arsenic, phosphorus, or antimony can be used as the n-type impurity. Boron can be used as the p-type impurity.

The conductive portion 10 and the gate electrode 20 include a conductive material such as polysilicon. An impurity may be added to the conductive material.

The first insulating portion 31, the second insulating portion 32, the insulating portion 33, the gate insulating portion 34, and the insulating portion 35 include an insulating material such as silicon oxide.

The drain electrode 41 and the source electrode 42 include a metal such as aluminum.

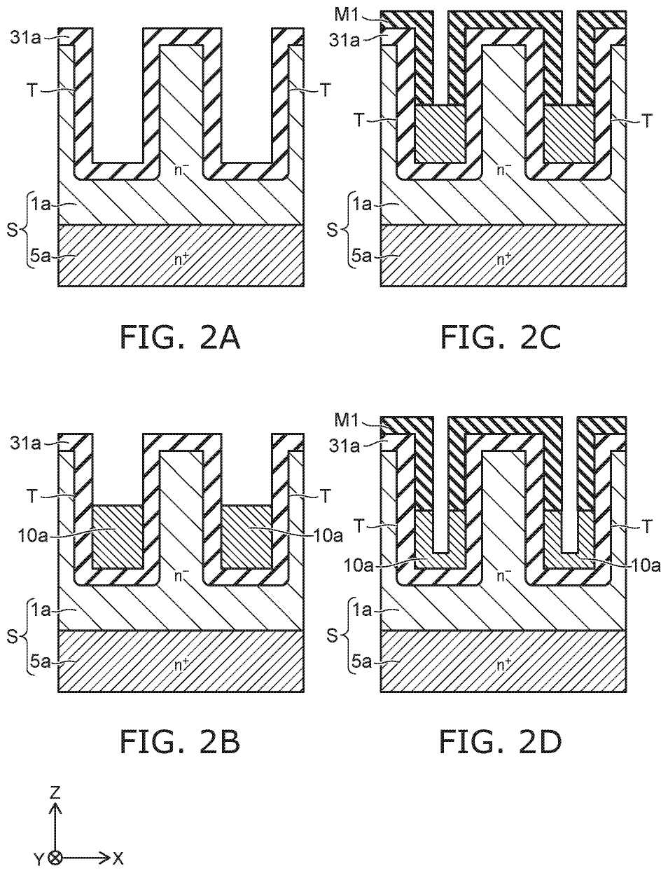

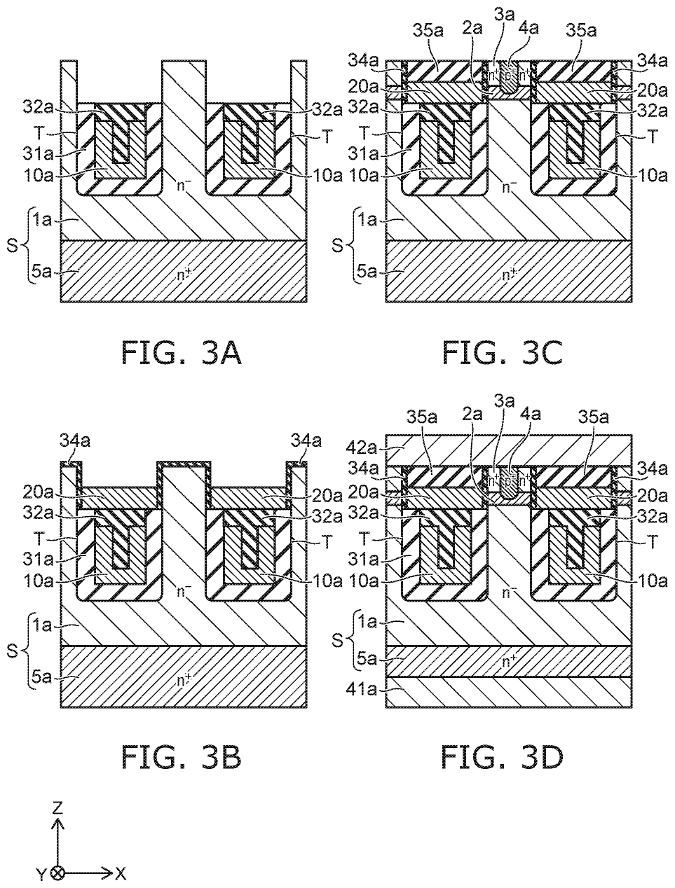

FIG. 2A to FIG. 2D and FIG. 3A to FIG. 3D are process cross-sectional views showing manufacturing processes of the semiconductor device according to the embodiment.

A semiconductor substrate S is prepared. The semiconductor substrate S includes an n⁺-type semiconductor region 5a and an n⁻-type semiconductor region la provided on the n⁺-type semiconductor region 5a. A plurality of trenches T extending along the Y-direction are formed on the upper surface of the n⁻-type semiconductor region la. By thermal oxidation of the semiconductor substrate 5, an insulating layer 31a is formed along the upper surface of the n⁻-type semiconductor region la and the inner surfaces of the trenches T as shown in FIG. 2A.

A conductive layer filling the trenches T is formed on the insulating layer 31a. The conductive layer is formed by chemical vapor deposition (CVD) of a conductive material such as polysilicon. The upper surface of the conductive layer is caused to recede by removing a portion of the conductive layer using chemical dry etching (CDE) or the like. Thereby, as shown in FIG. 2B, a plurality of conductive layers 10a provided separately inside the respective trenches T are formed.

As shown in FIG. 2C, a mask M1 is formed on the conductive layers 10a and the insulating layer 31a. A portion of the upper surface of each conductive layer 10a is not covered by the mask M1 and is exposed. The portion of each conductive layer 10a is removed by reactive ion etching (RIE) using the mask M1. As a result, as shown in FIG. 2D, the portion of the upper surface of each conductive layer 10a is caused to recede.

The mask M1 is removed, and another insulating layer is formed on the conductive layers 10a and the insulating layer 31a. The upper surface of the other insulating layer is caused to recede by CDE or wet etching. As a result, a plurality of insulating layers 32a provided separately inside the respective trenches T are formed. At this time, as shown in FIG. 3A, a portion of the insulating layer 31a is removed, and a portion of the surface of the n⁻-type semiconductor region la is exposed.

By thermal oxidation, an insulating layer 34a is formed on the exposed surface of the n⁻-type semiconductor region la. A conductive layer is formed on the insulating layers 32a and the insulating layer 34a. The upper surface of the conductive layer is caused to recede by CDE or wet etching. Thereby, as shown in FIG. 3B, a plurality of conductive layers 20a provided separately inside the respective trenches T are formed.

P-type impurities and n-type impurities are sequentially ion-implanted into a portion of the upper surface of the n⁻-type semiconductor region la located between adjacent trenches T to form a plurality of p-type semiconductor regions 2a, a plurality of n⁺-type semiconductor regions 3a, and a plurality of p⁺-type semiconductor regions 4a. Another insulating layer is formed on the conductive layers 20a and the insulating layer 34a. A portion of the other insulating layer and a portion of insulating layer 34a are polished by chemical mechanical polishing (CMP) until the n⁺-type semiconductor regions 3a and the p⁺-type semiconductor regions 4a are exposed as shown in FIG. 3C. Thereby, a plurality of insulating layers 35a respectively covering the conductive layers 20a are formed.

A metal layer 42a is formed on the n⁺-type semiconductor regions 3a, the pi-type semiconductor regions 4a, and the insulating layers 35a. The lower surface of the n⁺-type semiconductor region 5a is polished until the n⁺-type semiconductor region 5a has a prescribed thickness. A metal layer 41a is formed on the polished lower surface of the n⁺-type semiconductor region 5a as shown in FIG. 3D. Thus, the semiconductor device 100 according to the embodiment is manufactured.

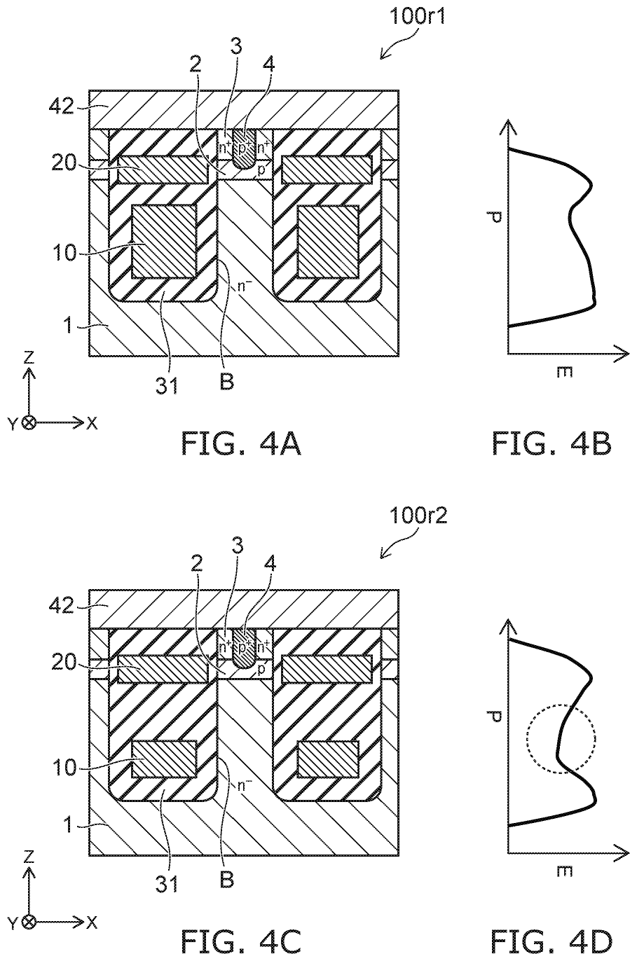

FIG. 4A and FIG. 4C are cross-sectional views respectively showing portions of semiconductor devices according to reference examples. FIG. 4B and FIG. 4D are graphs respectively showing characteristics of the semiconductor devices according to the reference examples.

The effects of the embodiment will be described with reference to FIG. 4A to FIG. 4D. FIG. 4A and FIG. 4C respectively show a portion of the semiconductor device 100r1 according to the reference example and a portion of the semiconductor device 100r2 according to the other reference example. FIG. 4B and FIG. 4D respectively show the characteristics of the semiconductor devices 100r1 and 100r2. Specifically, FIG. 4B and FIG. 4D show a relationship between the position P in the Z-direction and the electric field strength E on the interface B between the n⁻-type drift region 1 and the first insulating portion 31 that surrounds the conductive portion 10 and the gate electrode 20.

In the semiconductor device 100r1 and the semiconductor device 100r2, the shapes of the conductive portion 10 are different from that of the semiconductor device 100 shown in FIG. 1. In the semiconductor devices 100r1 and 100r2, the conductive portion 10 has a rectangular shape in the X-Z cross section. The conductive portion 10 of these semiconductor devices does not include the first conductive portion 11 and the second conductive portion 12.

When the semiconductor device is switched from the ON-state to the OFF-state (is turned off), a surge voltage is applied to the drain electrode 41 by the inductance of the electric circuit including the semiconductor device. When the surge voltage is applied, the potential of the drain electrode 41 vibrates. At this time, if the amplitude is large, malfunction may occur in the electric circuit, or circuit components of the electric circuit may be broken. Therefore, when the potential of the drain electrode 41 vibrates, it is desirable that the amplitude is small.

When the surge voltage is applied to the drain electrode 41, a current flows from the drain electrode 41 to the source electrode 42 through the first insulating portion 31 and the conductive portion 10. The amplitude of the potential of the drain electrode 41 increases as the current flowing through the conductive portion 10 increases. The magnitude of the current is inversely proportional to the magnitude of the electrical resistance of the conductive portion 10. Therefore, the higher the electrical resistance of the conductive portion 10 is, the smaller the amplitude of the potential of the drain electrode 41 can be

In the semiconductor device 100 according to the embodiment, the conductive portion 10 includes the first to third conductive portions 11 to 13. The first conductive portion 11 and the second conductive portion 12 are separated from each other in the X-direction. According to this structure, the cross-sectional area of the conductive portion 10 in the X-Z plane can be made smaller than that of the conductive portion 10 of the semiconductor device 100r1. As the cross-sectional area of the conductive portion 10 decreases, the electrical resistance of the conductive portion 10 increases. As a result, when the surge voltage is applied to the drain electrode 41, the amplitude of the potential of the drain electrode 41 can be reduced.

The structure of the conductive portion 10 shown in FIG. 4C can also increase the electrical resistance of the conductive portion 10 as compared with the structure of the conductive portion 10 shown in FIG. 4A. However, according to the structure shown in FIG. 4C, the distance in the Z-direction between the conductive portion 10 and the gate electrode 20 is long. Thus, as shown at a portion surrounded by a broken line in FIG. 4D, the electric field strength at the portion of the interface B decreases in comparison with the electric field strength distribution shown in FIG. 4B. An integral value of the electric field strength E at each position P corresponds to the breakdown voltage of the semiconductor device. Therefore, according to the structure of FIG. 4C, the noise can be reduced, but the breakdown voltage of the semiconductor device decreases as compared with the structure of FIG. 4A.

In the semiconductor device 100 according to the embodiment, the distance in the Z-direction between the conductive portion 10 (for example, the first conductive portion 11) and the gate electrode 20 does not change in comparison with the structure of FIG. 4A. Therefore, according to the embodiment, it is possible to suppress the noise of the semiconductor device 100 occurring at the turn-off, while suppressing the decrease in the breakdown voltage of the semiconductor device 100.

An impurity may be added to the gate electrode 20 in order to reduce the electrical resistance. An impurity may be added to the conductive portion 10 or may not be added to the conductive portion 10. It is desirable that the impurity concentration in the conductive portion 10 is lower than the impurity concentration in the gate electrode 20. By reducing the impurity concentration in the conductive portion 10, the electrical resistance of the conductive portion 10 can be increased. The impurity included in the conductive portion 10 and the gate electrode 20 may be n-type impurity or p-type impurity. For example, the conductive portion 10 and the gate electrode 20 include phosphorus as the impurity.

The conductive portion 10 and the gate electrode 20 may include plural kinds of n-type impurities or plural kinds of p-type impurities. In this case, a total concentration of each element functioning as the impurity is taken as the impurity concentration in each of the conductive portion 10 and the gate electrode 20.

The conductive portion 10 and the gate electrode 20 may include both the n-type impurity and the p-type impurity. In this case, a net impurity concentration after mutual compensation of these impurities is taken as the impurity concentration in each of the conductive portion 10 and the gate electrode 20.

When the impurity concentration in the conductive portion 10 is lower than the impurity concentration in the gate electrode 20, the conductive portion 10 may not include the first to third conductive portions 11 to 13. For example, the shape of the conductive portion 10 may be square in the X-Z cross-section as shown in FIG. 4A. By reducing the impurity concentration in the conductive portion 10, the electric resistance of the conductive portion 10 can be increased.

### (Modification)

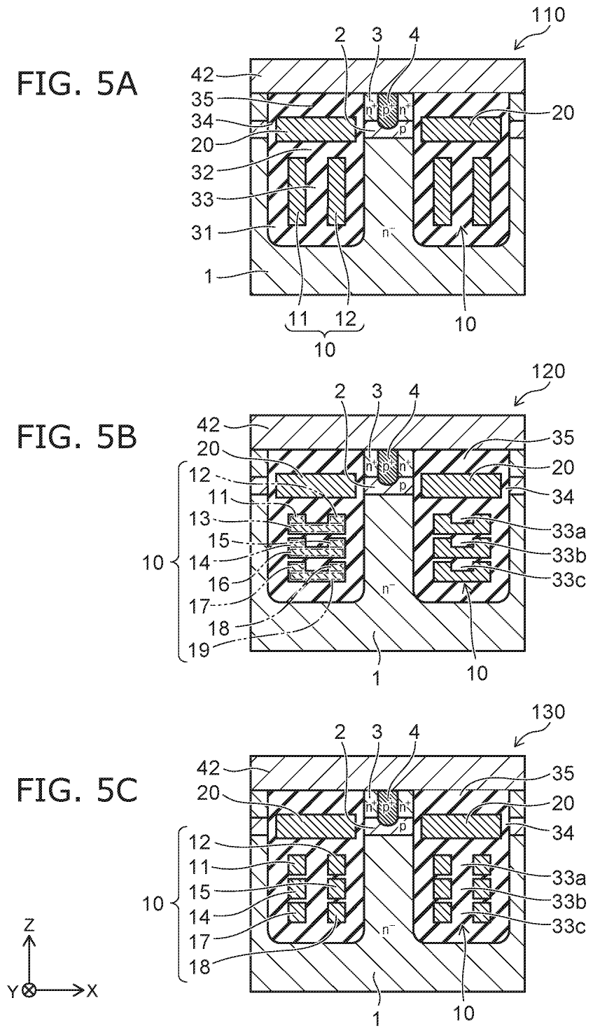

FIG. 5A to FIG. 5C are cross-sectional views respectively showing a portion of semiconductor devices according to modifications of the embodiment.

In the semiconductor device 110 shown in FIG. 5A, the conductive portion 10 includes only the first conductive portion 11 and the second conductive portion 12 separated from each other in the X-direction. The conductive portion 10 does not include the third conductive portion 13. According to the semiconductor device 110, the electrical resistance of the conductive portion 10 can be further increased as compared with the semiconductor device 100. Thereby, the noise occurring at the turn-off can be further reduced.

In the semiconductor device 120 shown in FIG. 5B, the conductive portion 10 further includes fourth to ninth conductive portions 14 to 19. The fourth conductive portion 14 and the fifth conductive portion 15 are separated from each other in the X-direction. The sixth conductive portion 16 connects the lower end of the fourth conductive portion 14 and the lower end of the fifth conductive portion 15. The seventh conductive portion 17 and the eighth conductive portion 18 are separated from each other in the X-direction. The ninth conductive portion 19 connects the lower end of the seventh conductive portion 17 and the lower end of the eighth conductive portion 18.

The first to third conductive portions 11 to 13 are provided on the fourth to sixth conductive portions 14 to 16 and are separated from the fourth to sixth conductive portions 14 to 16. The fourth to sixth conductive portions 14 to 16 are provided on the seventh to ninth conductive portions 17 to 19 and are separated from the seventh to ninth conductive portions 17 to 19.

Insulating portions 33a to 33c are respectively provided between the first conductive portion 11 and the second conductive portion 12, between the fourth conductive portion 14 and the fifth conductive portion 15, and between the seventh conductive portion 17 and the eighth conductive portions 18 in the X-direction. According to the semiconductor device 120, similar to the semiconductor device 100, the electrical resistance of the conductive portion 10 can be increased, and the noise occurring at the turn-off can be reduced.

The semiconductor device 130 shown in FIG. 5C does not include the third conductive portion 13, the sixth conductive portion 16, and the ninth conductive portion 19 in comparison with the semiconductor device 120. According to the semiconductor device 130, the electrical resistance of the conductive portion 10 can be further increased compared to the semiconductor device 120, and the noise occurring at the turn-off can be further reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode,
a first semiconductor region provided on the first electrode, the first semiconductor region being of a first conductivity type and being electrically connected to the first electrode;
a second semiconductor region provided on the first semiconductor region, the second semiconductor region being of a second conductivity type;
a third semiconductor region selectively provided on the second semiconductor region, the third semiconductor region being of the first conductivity type;
a conductive portion provided inside the first semiconductor region with a first insulating portion interposed, the conductive portion including a first conductive portion and a second conductive portion separated from each other in a first direction perpendicular to a second direction, the second direction being from the first electrode toward the first semiconductor region,
a gate electrode provided on the conductive portion with a second insulating portion interposed, the gate electrode opposing, with a gate insulating portion interposed, a portion of the first semiconductor region, the second semiconductor region, and the third semiconductor region in the first direction; and
a second electrode provided on the second semiconductor region, the third semiconductor region, and the gate electrode, the second electrode being electrically connected to the second semiconductor region, the third semiconductor region, and the conductive portion.

2. The device according to claim I, wherein
a length in the second direction of the first conductive portion is longer than a length in the first direction of the first conductive portion, and
a length in the second direction of the second conductive portion is longer than a length in the first direction of the second conductive portion.

3. The device according to claim 1, wherein the conductive portion further includes a third conductive portion connecting a lower end of the first conductive portion and a lower end of the second conductive portion.

4. The device according to claim 1, wherein
the conductive portion further includes a fourth conductive portion and a fifth conductive portion separated from each other in the first direction, and
the fourth conductive portion and the fifth conductive portion are respectively provided on the first conductive portion and the second conductive portion, and
the fourth conductive portion and the fifth conductive portion are separated from the first conductive portion and the second conductive portion.

5. The device according to claim 1, wherein
the conductive portion and the gate electrode include an impurity, and
an impurity concentration in the conductive portion is lower than an impurity concentration in the gate electrode.

6. A semiconductor device, comprising:
a first electrode,
a first semiconductor region provided on the first electrode, the first semiconductor region being of a first conductivity type and being electrically connected to the first electrode;
a second semiconductor region provided on the first semiconductor region, the second semiconductor region being of a second conductivity type;
a third semiconductor region selectively provided on the second semiconductor region, the third semiconductor region being of the first conductivity type;
a conductive portion provided inside the first semiconductor region with a first insulating portion interposed, the conductive portion including an impurity;
a gate electrode provided on the conductive portion with a second insulating portion interposed, the gate electrode opposing, with a gate insulating portion interposed, a portion of the first semiconductor region, the second semiconductor region, and the third semiconductor region in a first direction perpendicular to a second direction, the second direction being from the first electrode toward the first semiconductor region, the gate electrode including an impurity, an impurity concentration in the gate electrode being higher than an impurity concentration in the conductive portion; and
a second electrode provided on the second semiconductor region, the third semiconductor region, and the gate electrode, the second electrode being electrically connected to the second semiconductor region, the third semiconductor region, and the conductive portion.
